(19) United States
(12) Patent Application Publication
(10) Pub. No.: US 2025/0151623 A1
(43) Pub. Date: May 8, 2025

(54) METHOD FOR DESIGNING PIEZOELECTRIC ELEMENT UNIT, ULTRASONIC ELEMENT HAVING THE PIEZOELECTRIC ELEMENT UNIT MANUFACTURED USING THE SAME, METHOD FOR MANUFACTURING THE ULTRASONIC ELEMENT, AND ACOUSTIC PRESSURE FOCUSING DEVICE HAVING THE ULTRASONIC ELEMENT

(71) Applicants: KOREA INSTITUTE OF MACHINERY & MATERIALS, Daejeon (KR); INDUSTRY-UNIVERSITY COOPERATION FOUNDATION HANYANG UNIVERSITY, Seoul (KR)

(72) Inventors: Shin HUR, Sejong (KR); Kyungjun SONG, Daejeon (KR); Gilho YOON, Incheon (KR); Hyunggyu CHOI, Uijeongbu-si (KR)

(21) Appl. No.: 19/003,089

(22) Filed: Dec. 27, 2024

Related U.S. Application Data
(63) Continuation of application No. 17/294,672, filed on May 17, 2021.

(30) Foreign Application Priority Data
Nov. 29, 2018 (KR) 10-2018-0151316

(51) Int. Cl. H10N 30/03; H04R 17/00; H10N 30/20; H10N 30/87; H10N 30/88

(52) U.S. Cl. CPC H10N 30/03; H10N 30/20; H10N 30/87; H10N 30/88; H04R 17/00

(57) ABSTRACT

A method for designing a piezoelectric element unit, a ultrasonic element having the piezoelectric element manufactured using the method, a method for manufacturing the ultrasonic element, and an acoustic pressure focusing device having the ultrasonic element are provided. In the method for designing a piezoelectric element unit, a target position and a target distance are selected. A basic information of a piezoelectric element base material is inputted. Each of a plurality of grids is grouped into a unit grid group. A size of an output acoustic pressure outputted at each unit grid group is calculated. The unit grid group outputting the output acoustic pressure included in a range of a reference acoustic pressure among a plurality of the unit groups is decided. The plurality of ring patterns being concentric is determined based on a pattern shape information.

### CROSS-REFERENCE TO RELATED APPLICATION

This present application is a Continuation of U.S. patent application Ser. No. 17/294,672, filed on May 17, 2021, which is a national stage filing under 35 U.S.C § 371 of PCT application number PCT/KR2019/014815 filed on Nov. 4, 2019, which is based upon and claims the benefit of priority to Korean Patent Application No. 10-2018-0151316 filed Nov. 29, 2018 in the Korean Intellectual Property Office. The disclosures of the above-listed applications are hereby incorporated by reference herein in their entireties.

### BACKGROUND

### 1. Field of Disclosure

The present disclosure of invention relates to a method for designing a piezoelectric element unit, a ultrasonic element having the piezoelectric element manufactured using the method, a method for manufacturing the ultrasonic element, and an acoustic pressure focusing device having the ultrasonic element, and more specifically the present disclosure of inventions relates to a method for designing a piezoelectric element unit, a ultrasonic element having the piezoelectric element manufactured using the method, a method for manufacturing the ultrasonic element, and an acoustic pressure focusing device having the ultrasonic element, capable of increasing focusing intensity of acoustic pressure and focusing an acoustic sound more correctly and precisely.

### 2. Description of Related Technology

Conventional drug treatment or radiation treatment for a cancer is hard to be selectively applied to the cancer, and thus side effect may be inevitable. Recently, high intensity focused ultrasound (HIFU) is in the spotlight as a selective cancer treatment, and the HIFU has been widely applied.

Normally, a HIFU converter is divided into a single device type converter and an array type converter.

In the single device type converter, a heat is transmitted to a fixed focus which is determined by a structure of the converter. In the array type converter, the focus may be variably changed, and thus the array type converter is normally used for a HIFU element for treating a clinical tumor.

In addition, conventionally, in the HIFU element, a concaved-shape multi-channel array structure is normally used. In the HIFU element, an intensity of the ultrasound is increased to focus an acoustic pressure to a target area, so as to increase the temperature of the target area in a range between 60° C. and 90° C., and then the tumor is eliminated.

FIG. 1A and FIG. 1B illustrate a shape of an acoustic pressure generated in the conventional ultrasonic element.

Referring to FIG. 1A, the conventional ultrasonic element 10 has a curved shape, and generates the acoustic pressure to be focused at a target position PT. Thus, in the conventional ultrasonic element 10, the size of the ultrasonic element should be increased according to the change of the target position PT at which the acoustic pressure is focused.

In addition, in treating, lots of unnecessary impedance matching layers are filled in the curved surface, and as the size of the ultrasonic element 10 increases, the space for the ultrasonic element is also increased and the insertion of the ultrasonic element is more uncomfortable.

In addition, an ideal acoustic pressure has a relatively smaller size from a setup position P1 close to the target position PT and then has a maximum size at the target position PT. However, the conventional ultrasonic element 10 is hard to have the above mentioned ideal acoustic pressure.

Referring to FIG. 1B, the acoustic pressure generated from the ultrasonic element is maximum at the target position PT, but the acoustic pressure may be focused at several areas between the setup position P1 and the target position PT. The above multi-focused acoustic pressure may cause a side effect. For example, the cells except for the cancer may be damaged and thus the damaged cells should be recovered.

Related prior art is Korean patent No. 10-1195671.

### SUMMARY

The present invention is developed to solve the above-mentioned problems of the related arts. The present invention provides a method for designing a piezoelectric element unit capable of increasing focusing intensity of acoustic pressure and focusing an acoustic sound more correctly and precisely.

In addition, the present invention also provides a ultrasonic element having the piezoelectric element manufactured using the method for designing the piezoelectric element unit.

In addition, the present invention also provides a method for manufacturing the ultrasonic element.

In addition, the present invention also provides an acoustic pressure focusing device having the ultrasonic element.

According to an example embodiment, in a method for designing a piezoelectric element unit having a plurality of ring patterns being concentric, a target position at which a maximum acoustic pressure is focused and a target distance to the target position are selected. A basic information of a piezoelectric element base material having a circular shape is inputted. Each of a plurality of grids is grouped into a unit grid group. A cross-section of the piezoelectric element base material along a height direction is divided into the plurality of girds which is formed along the height direction and a radial direction of the piezoelectric element base material. A size of an output acoustic pressure outputted at each unit grid group is calculated. The unit grid group outputting the output acoustic pressure included in a range of a reference acoustic pressure among a plurality of the unit groups is decided. The reference acoustic pressure is predetermined based on the maximum acoustic pressure, the target position and the target distance. The plurality of ring patterns being concentric is determined based on a pattern shape information having a position and a width included in each of the decided unit grid groups, from the piezoelectric element base material.

In an example, after a plurality of the target positions is selected, the piezoelectric element unit may output an acoustic pressure so as to focus the maximum acoustic pressure required at each of the target positions.

According to another example embodiment, an ultrasonic element includes a piezoelectric element unit, a lower electrode and an upper electrode. The piezoelectric element unit has the plurality of ring patterns being concentric. The piezoelectric element unit is manufactured using the method for designing the piezoelectric element unit. The lower electrode is disposed under the piezoelectric element unit. The upper electrode is disposed on the piezoelectric element unit.

In an example, the piezoelectric element unit may further have a connecting pattern formed along a radial direction and connecting the ring patterns. The upper electrode may include upper ring electrodes disposed on the ring pattern and spaced apart from each other, and an upper connecting electrode disposed on the connecting pattern and connecting the upper ring electrodes with each other.

In an example, the piezoelectric element unit may have a base integrally formed under the ring patterns, and the lower electrode may be entirely formed under the base.

In an example, the piezoelectric element unit may further include a connecting pattern formed along a radial direction and connecting the ring patterns, and the ring patterns are separated except for the connecting pattern. The lower electrode may include lower ring electrodes disposed under the ring pattern and spaced apart from each other, and a lower connecting electrode disposed under the connecting pattern and connecting the lower ring electrodes with each other.

According to still another example embodiment, a method for manufacturing an ultrasonic element includes preparing a lower electrode having a circular plate shape, forming a piezoelectric element base material on the lower electrode, forming an upper electrode on the piezoelectric element base material, and machining the upper electrode and the piezoelectric element base material at the same time via a laser machining, so as to form a plurality of ring patterns having a ring shape based on a pattern shape information of the method for designing the piezoelectric element unit.

In an example, in the machining, an irradiated laser may pass through the upper electrode and may be blocked by the piezoelectric element base material, so that a lower portion of the piezoelectric element base material may remain to be connected.

In an example, in the machining, an irradiated laser may pass through the upper electrode, the piezoelectric element base material and the lower electrode, so that the upper electrode, the piezoelectric element base material and the lower electrode may be separated after the machining.

According to still another example embodiment, an acoustic pressure focusing device includes the ultrasonic element, an absorbing part, an inner housing and an outer housing. The absorbing part is disposed at a rear of the ultrasonic element and configured to absorb an ultrasonic wave generated by the ultrasonic element. The inner housing is configured to enclose an outer surface of the ultrasonic element and the absorbing part. The outer housing is configured to receive the inner housing and is configured to expose a front of the ultrasonic element outwardly.

In an example, the acoustic pressure focusing device may further include a coating layer configured to cover the outer housing and the ultrasonic element.

In an example, the coating layer may be further filled in a gap formed at the ultrasonic element.

In an example, the acoustic pressure focusing device may further include an impedance matching part disposed between the upper electrode and the coating layer, or disposed at the gap of the ultrasonic element.

According to the present example embodiments, the piezoelectric element unit may focus the acoustic pressure on the target position. Thus, the acoustic pressure may not be focused in other areas except for the target position, and the cell damage like a burn may be prevented in the ultrasonic treatment.

### BRIEF DESCRIPTION OF THE DRAWINGS

FIG. 1A and FIG. 1B illustrate a shape of an acoustic pressure generated in the conventional ultrasonic element;

FIG. 2 is a perspective view illustrating an acoustic pressure focusing device according to an example embodiment of the present invention;

FIG. 3 is an exploded perspective view illustrating the acoustic pressure focusing device of FIG. 2;

FIG. 4 is a perspective view illustrating an ultrasonic element of the acoustic pressure focusing device of FIG. 2;

FIG. 5A and FIG. 5B are cross-sectional views illustrating a line A-A′ of FIG. 4;

FIG. 6 is a flow chart showing a method for designing a piezoelectric element unit according to another example embodiment of the present invention;

FIG. 7A, FIG. 7B, FIG. 8A and FIG. 8B are processing views illustrating the method for designing the piezoelectric element unit of FIG. 6;

FIG. 9 is a flow chart showing a method for manufacturing the ultrasonic element according to still another example embodiment of the present invention; and

FIG. 10A, FIG. 10B, FIG. 10C and FIG. 10D are processing views illustrating the method for manufacturing the ultrasonic element of FIG. 9.

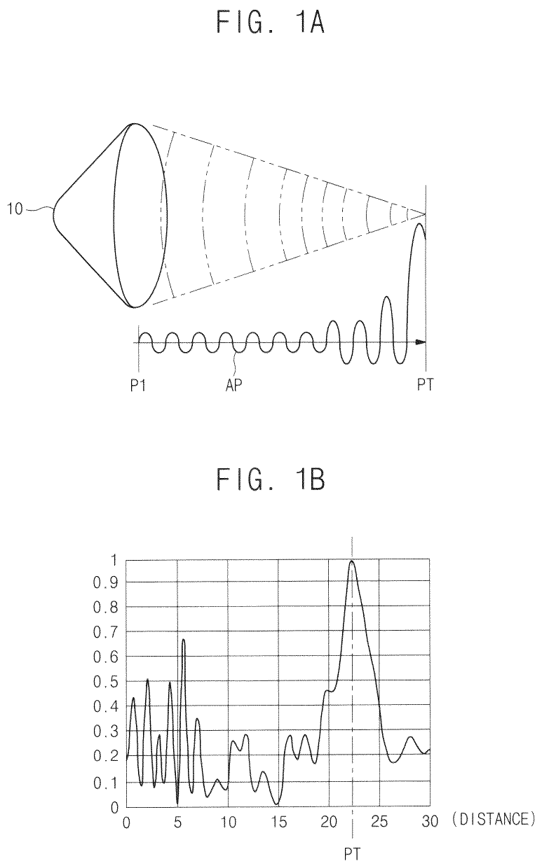

* Reverence numerals

| | |
|---|---|
| 100: ultrasonic device | 110: piezoelectric element unit |
| 111, 111a, 111b: ring pattern | 112: connecting pattern |
| 113: base | 120: lower electrode |
| 121: lower ring electrode | 122: lower connecting electrode |
| 130: upper electrode | 131: upper ring electrode |
| 132: upper connecting | 160: piezoelectric element base |
| electrode | material |
| 162, 162a: grid | 163, 163a: unit grid group |
| 200: absorbing part | 250: impedance matching part |
| 300: inner housing | 350: outer housing |
| 400: coating layer | |

### DETAILED DESCRIPTION

The invention is described more fully hereinafter with Reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention. Spatially relative terms, such as “beneath,” “below,” “lower,” “above,” “upper” and the like, may be used herein for ease of description to describe one element or feature's relationship to another element(s) or feature(s) as illustrated in the figures.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The invention is described more fully hereinafter with reference to the accompanying drawings, in which embodiments of the invention are shown.

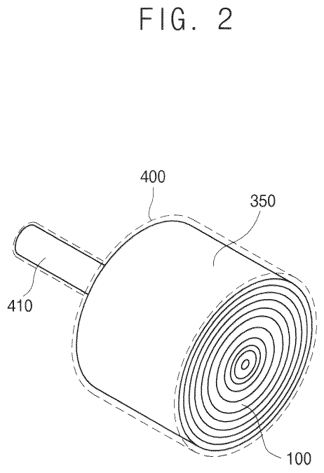

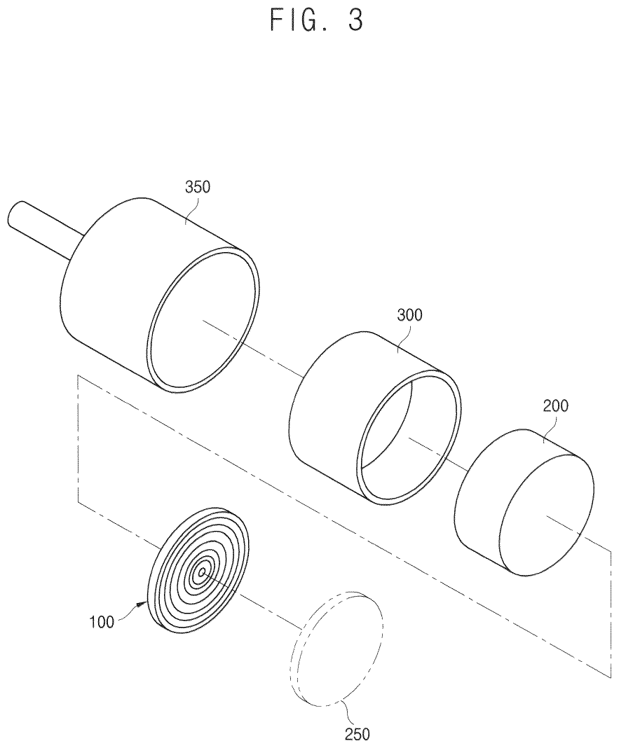

FIG. 2 is a perspective view illustrating an acoustic pressure focusing device according to an example embodiment of the present invention. FIG. 3 is an exploded perspective view illustrating the acoustic pressure focusing device of FIG. 2.

Referring to FIG. 2 and FIG. 3, the acoustic pressure focusing device includes an ultrasonic element 100, an absorbing part 200, an inner housing 300 and an outer housing 350.

For the convenience of the explanation, along an advancing direction of an ultrasonic wave generated from the ultrasonic element 100, a front, a front portion or forwardly and a rear, a rear portion or backwardly are defined. For example, when the ultrasonic wave advances from a first point to a second point, the first point is defined as the rear, the rear portion or backwardly and the second point is defined as the front, the front portion or forwardly.

The ultrasonic element 100 includes a piezoelectric element unit, and the ultrasonic element 100 is explained below.

The absorbing part 200 is disposed at the rear of the ultrasonic element 100. The absorbing part 200 absorbs the ultrasonic wave generated from the ultrasonic element 100, and prevents a reflective wave of the ultrasonic wave from advancing forwardly.

The absorbing part 200 disperses or absorbs the ultrasonic wave transmitting to the absorbing part 200 and eliminates the reflective wave, to prevent unnecessary signal from being interfered.

The inner housing 300 encloses an outer surface of the ultrasonic element 100 and the absorbing part 200. The inner housing 300 is tightly attached to the outer surface of the ultrasonic element 100 and the absorbing part 200, to fix the ultrasonic element 100 and the absorbing part 200. The inner housing 300 absorbs the ultrasonic wave or prevents the reflection of the ultrasonic wave, and may include low density epoxy.

The outer housing 350 receives the inner housing 300. A front of the ultrasonic element 100 may be exposed outwardly from the outer housing 350 with the outer housing 350 receiving the inner housing 300.

A transmitting line (not shown) and a cable 410 may be connected to the rear of the outer housing 350. The transmitting line transmits a power and a control signal to the ultrasonic element 100. The cable 410 receives a signal line (not shown) of a connector (not shown) connected to the ultrasonic element 100 to transmit or receive an electric signal.

The acoustic pressure focusing device may further include a coating layer 400. The coating layer 400 covers the outer housing 350 and the ultrasonic element 100. The acoustic pressure focusing device may be covered by the coating layer 400. The coating layer 40 may be a waterproof for the acoustic pressure focusing device, when the acoustic pressure focusing device is inserted into a body.

In addition, the acoustic pressure focusing device may further include an impedance matching part 350. The impedance matching part 250 is disposed between a front surface of the ultrasonic element 100 and the coating layer 400. High energy transmittance is necessary for a high intensity focused ultrasound. For example, when the ultrasonic wave is incident into a matter having relatively larger impedance like a skull in addition to a soft tissue like a skin, relatively lower acoustic energy may be transmitted due to an impedance mismatch. Here, the impedance matching part 250 connects an incident area of the ultrasonic wave with a transmitting area of the ultrasonic wave, to improve a difference of the impedance, so that the transmittance of the ultrasonic wave may be increased. The impedance matching part 250 may include the low density epoxy.

A thickness of the impedance matching part 250 is changed according to an operating frequency of the ultrasonic wave generated by the ultrasonic element 100.

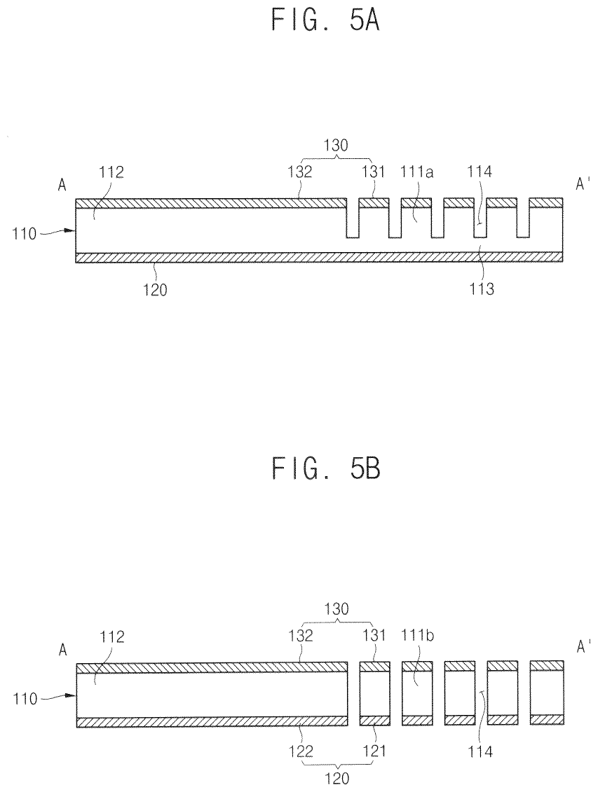

The impedance matching part 250 may be disposed at a gap 114 (FIG. 5A and FIG. 5B) of a ring pattern 111a and 111b (FIG. 5A and FIG. 5B) of the ultrasonic element 100. For example, the impedance matching part 250 may be disposed between the front surface of the ultrasonic element 100 and the coating layer 400, or one of the gaps 114 formed in the ultrasonic element 100.

In addition, when the impedance matching part 250 is disposed between the front surface of the ultrasonic element 100 and the coating layer 400, the coating layer 400 may be disposed at the gap 114 formed in the ultrasonic element 100, instead of the impedance matching part 250.

Hereinafter, the ultrasonic element 100 is explained in detail.

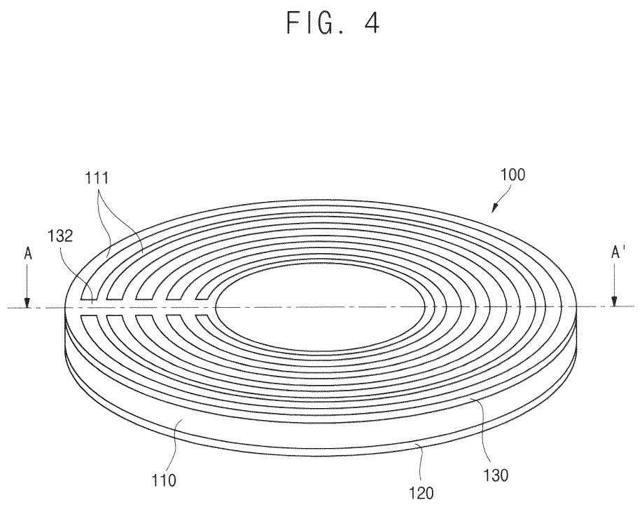

FIG. 4 is a perspective view illustrating an ultrasonic element of the acoustic pressure focusing device of FIG. 2. FIG. 5A and FIG. 5B are cross-sectional views illustrating a line A-A′ of FIG. 4.

Referring to FIG. 4, FIG. 5A and FIG. 5B, the ultrasonic element 100 includes a piezoelectric element unit 110, a lower electrode 120 and an upper electrode 130.

The piezoelectric element unit 110 may be a plate shape, such as a disk, and includes a plurality of ring patterns 111. Here, all of the ring patterns 111 are concentric. In the piezoelectric element unit 110, a vibrating frequency is determined according to a shape of the ring pattern 111.

Hereinafter, a method for designing the piezoelectric element unit is explained. The piezoelectric element is designed based on the ring pattern 111.

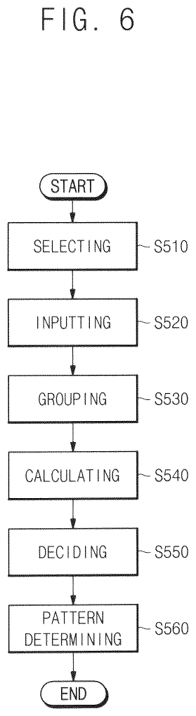

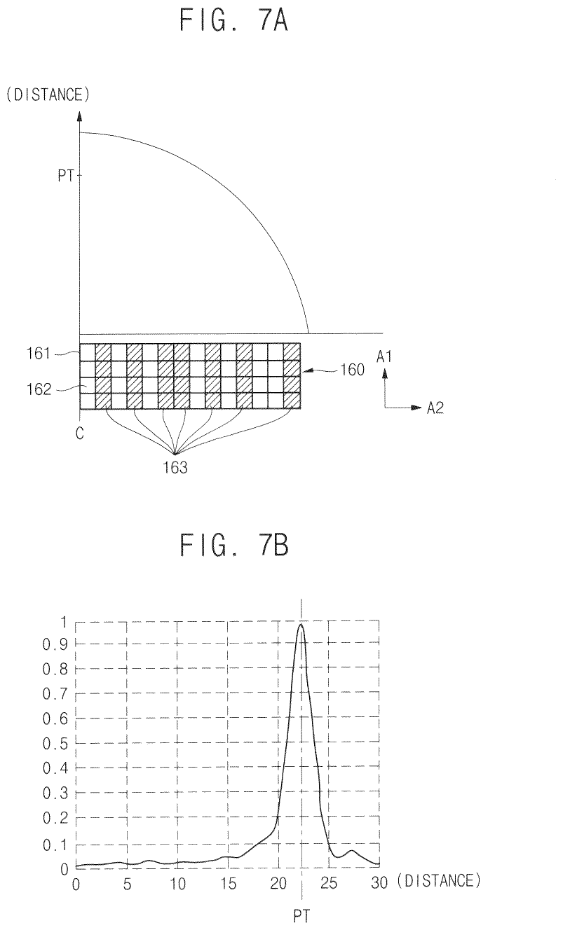

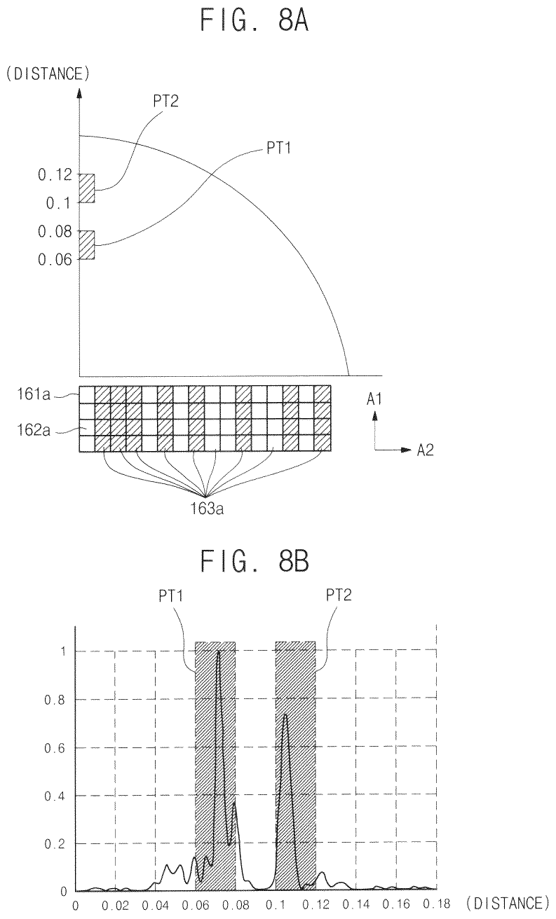

FIG. 6 is a flow chart showing a method for designing a piezoelectric element unit according to another example embodiment of the present invention. FIG. 7A, FIG. 7B, FIG. 8A and FIG. 8B are processing views illustrating the method for designing the piezoelectric element unit of FIG. 6.

Referring to FIG. 6, FIG. 7A and FIG. 7B, the method for designing the piezoelectric element unit includes a selecting (step S510), an inputting (step S520), a grouping (step S530), a calculating (step S540), a deciding (step S550) and a pattern determining (step S560).

In the selecting (step S510), a target position PT and a target distance to the target position PT are selected. Here, the target position PT is defined as a position at which a maximum acoustic pressure is focused.

In the inputting (step S520), a basic information of a circular plate shape piezoelectric element base material is inputted. Here, the piezoelectric element base material is machined to be formed as a piezoelectric element unit.

In the inputting (step S520), the basic information includes the information on a piezoelectric element base material such a material, a height, a diameter and so on, the maximum acoustic pressure focused at the target position PT, a power applied to the piezoelectric element unit, and so on.

In the grouping (step S530), a cross section 161 of the piezoelectric element base material 160 along a height direction, is divided into a plurality of grids 162. The grids 162 are arranged along the height direction A1 and a radial direction A2 of the piezoelectric element base material 160. Then, the grids 162 arranged along the height direction A1 are grouped as a unit grid group 162.

Here, as illustrated in FIG. 7A, a cross section of a first side with respect to a center C of the base material 160 among the cross sections of the base material 160 along the height direction, may be divided into the plurality of grids 162 arranged along the height direction A1 and the radial direction A2. Here, the height and the diameter of the piezoelectric element base material 160 may be predetermined according to the base information inputted in the inputting (step S520).

In the calculating (step S540), to focus the maximum acoustic pressure at the target position PT, a size of the output acoustic pressure outputted at each unit grid group 163 is calculated.

As the power is supplied, the piezoelectric element unit generates a frequency, and the frequency is transmitted with resonance, attenuation and so on, and then the frequency is focused at the target position as the acoustic pressure is controlled.

In the calculating (step S540), to focus a target acoustic pressure AP selected in the selecting (step S510) to the target position PT, the acoustic pressure generated at each unit grid group 163 is calculated.

Accordingly, after the selecting (step S510) and the inputting (step S520), a reference acoustic pressure is determined based on the maximum acoustic pressure, the target position PT and the target distance. The reference acoustic pressure may be an acoustic pressure outputted by the ring pattern which is formed later, to focus the target acoustic pressure at the target position PT, and the reference acoustic pressure may be in a predetermined range.

In the deciding (step S550), among the plurality of unit grid groups 163, the specific unit grid group is decided. Here, the specific unit grid group outputs the output acoustic pressure included in the predetermined range of the reference acoustic pressure which is determined based on the maximum acoustic pressure, the target position PT and the target distance.

In the deciding (step S550), the output acoustic pressure at each unit grid group 163 is compared to the reference acoustic pressure, and then the specific unit grid group outputting the output acoustic pressure included in the range of the reference acoustic pressure is decided and selected.

In the pattern determining (step S560), the plurality of ring patterns, each being a concentric, is determined, based on the pattern shape information including a position and a width corresponding to each unit grid group 163, from the piezoelectric element base material. Here, the position and the width of each unit grid group 163 are decided and selected by the deciding (step S550).

For example, referring to FIG. 7A, when a hatched unit grid group 163 is decided into the unit grid group 163 outputting the acoustic pressure over the reference acoustic pressure, the unit grid group 163 not selected by the following laser machining is removed and the selected unit grid group 163 is remained as the ring pattern.

Accordingly, the piezoelectric element unit designed by above-mentioned method, as illustrated in FIG. 7B, focuses the target acoustic pressure to the target position PT.

In FIG. 7B, a vertical axis means a value of the acoustic pressure squared divided by the maximum acoustic pressure squared, and is expressed as Equation 1.

$$\frac{{\vert p \vert}^{2}}{max ( {\vert p \vert}^{2} )} \qquad Equation 1$$

Here, ‘p’ is the acoustic pressure and ‘max p’ is the maximum acoustic pressure.

Thus, when the value of Equation 1 is ‘1’, the generated acoustic pressure becomes the maximum value.

Referring to FIG. 7B, the piezoelectric element unit according to the present example embodiment focuses the target acoustic pressure to the target position PT. Thus, the acoustic pressure is not focused at other positions except for the target position PT, and thus the cell damage like a burn may be prevented in the ultrasonic treatment.

Referring to FIG. 8A and FIG. 8B, in the selecting (step S510), the plurality of target positions PT1, PT2 is selected.

Here, in the inputting (step S520), the maximum acoustic pressure is inputted at each of the target positions PT1 and PT2, and then the output acoustic pressure is determined based on the maximum acoustic pressure at each position.

Then, in the deciding (step S550), among the plurality of unit grid groups 163a which is formed in the cross section 161a of the piezoelectric element base material formed according to the inputted reference information, the specific unit grid group is decided. Here, the specific unit grid group outputs the output acoustic pressure included in the predetermined range of the reference acoustic pressure. In the pattern determining (step S560), the pattern shape information is obtained based on the specific unit grid group, and the plurality of ring patterns is determined.

The piezoelectric element unit 110 is manufactured based on the obtained pattern shape information obtained above, and the piezoelectric element unit 110 has the plurality of ring patterns 111 each of which is concentric, and thus the acoustic pressure may be outputted to focus the maximum acoustic pressure at each target position.

The lower electrode 120 is disposed under or beneath the piezoelectric element unit 110, and the lower electrode 120 is combined with the inner housing 300 to face the absorbing part 200.

The upper electrode 130 is disposed on the piezoelectric element unit 110, and the upper electrode 130 is partially exposed forwardly.

Here, the ring pattern 111 may be only disposed on the piezoelectric element unit 100, or may be also disposed under the piezoelectric element unit 110.

Thus, the upper electrode 130 has an upper ring electrode 131 having a ring shape and corresponding to the ring pattern 111. The upper ring electrode 131 corresponds to the ring pattern 111, and when the upper ring electrode 131 is not connected with adjacent upper ring electrode 131, the line for supplying a power is connected to each upper ring electrode 131. When the power is supplied to the lower electrode 120 and the upper electrode 130, the ultrasonic wave is generated forwardly from the piezoelectric element unit 110.

The piezoelectric element unit 110 may further include a connecting pattern 112 which is formed along the radial direction and connects the plurality of ring patterns 111 with each other.

Here, the upper electrode 130 may include an upper connecting pattern 132.

As explained above, the upper ring electrode 131 is formed on the ring pattern 111 and has a shape corresponding to the ring pattern 111. Here, the upper ring electrodes 131 are spaced apart from each other, and thus the upper connecting electrode 132 disposed on the connecting pattern 112 connects the upper ring electrodes 131 with each other. The line for supplying the power is connected to a portion of the upper electrode 131 and thus the line for supplying the power may be formed or connected more simply.

Referring to FIG. 5A, the piezoelectric element unit 110 includes a base 113 which is integrally formed under or beneath the plurality of ring patterns 111a.

Here, the lower electrode 120 is formed all under the base 113, and the line for supplying the power is connected to a portion of the lower electrode 120, so that the line for supplying the power may be formed or connected more simply.

Alternatively, referring to FIG. 5B, the piezoelectric element unit 110 may be also formed under or beneath the piezoelectric element unit 110 of the ring pattern 111b, and may further include a connecting pattern 112. Here, the plurality of ring patterns 111b is separated with each other except for the connecting pattern 112.

Then, the lower electrode 120 may include a lower ring electrode 121 and a lower connecting electrode 122.

The lower ring electrode 121 is formed under or beneath the ring pattern 111, and the lower ring electrodes 121 are spaced apart from each other. The lower connecting electrode 122 is disposed under or beneath the connecting pattern 112 and connects the lower ring electrodes 121 with each other. Here, the line for supplying the power is connected to a portion of the lower electrode 120, and thus the line for supplying the power may be formed or connected more simply.

The ultrasonic element according to the present example embodiment has a planer shape, and thus may be minimized compared to the conventional curved shape ultrasonic element. Thus, when the ultrasonic element is inserted into a body, the patient may feel more comfortable and the space for the ultrasonic element is decreased. In addition, the ultrasonic element may make a surface contact with the target, and thus the treatment may be more simplified and effective.

Hereinafter, the method for manufacturing the ultrasonic element is explained.

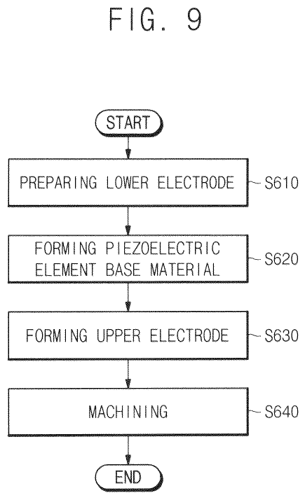

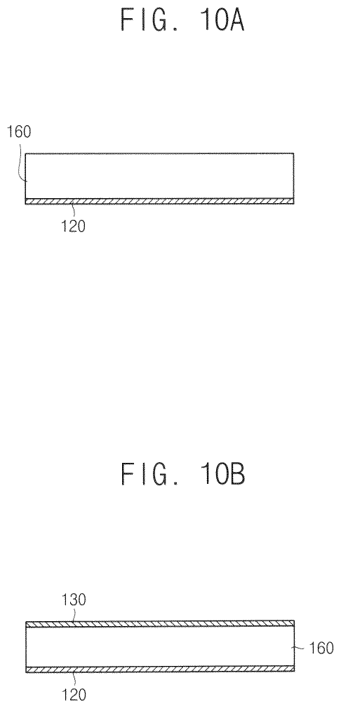

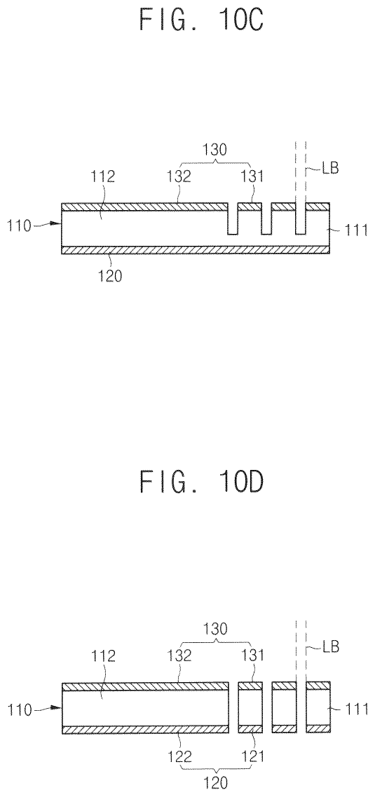

FIG. 9 is a flow chart showing a method for manufacturing the ultrasonic element according to still another example embodiment of the present invention. FIG. 10A, FIG. 10B, FIG. 10C and FIG. 10D are processing views illustrating the method for manufacturing the ultrasonic element of FIG. 9.

Referring to FIG. 9, FIG. 10A, FIG. 10B, FIG. 10C and FIG. 10D, the method for manufacturing the ultrasonic element includes preparing a lower electrode (step S610), forming a piezoelectric element base material (step S620), forming an upper electrode (step S630), and machining (step S640).

In the preparing the lower electrode (step S610), the lower electrode 120 having a circular plate or planar shape is prepared. Here, the lower electrode 120 has a diameter corresponding to the diameter of the piezoelectric element base material inputted from the inputting of the method for designing the piezoelectric element unit mentioned above.

In the forming the piezoelectric element base material (step S620), the piezoelectric element base material 160 is entirely formed on the lower electrode 120. Here, the piezoelectric element base material 160 is formed via depositing a piezoelectric element material on the lower electrode (referring to FIG. 10A).

In the forming the upper electrode (step S630), the upper electrode 130 is entirely formed on the piezoelectric element base material 160 (referring to FIG. 10B).

In the machining (step S640), the upper electrode 130 and the piezoelectric element base material 160 are machined via a laser machining at the same time, based on the pattern shape information from the method for designing the piezoelectric element unit, to form the plurality of ring patterns having a ring shape

Here, referring to FIG. 10C, in the machining (step S640), the laser LB passes through the upper electrode 130 and is blocked by the piezoelectric element base material 160, and thus a lower portion of the piezoelectric element base material 160 is remained to be connected.

Thus, the piezoelectric element unit 110 has the ring pattern 111 and the connecting pattern 112, and the upper electrode 130 has the upper ring electrode 131 and the upper connecting electrode 132. In addition, the lower electrode 120 is entirely formed under or beneath the piezoelectric element unit 110.

Alternatively, referring to FIG. 10D, in the machining, the laser LB passes through the upper electrode 130, the piezoelectric base material 160 and lower electrode 120, to form the upper electrode 130, the ring pattern 111 and the lower electrode 120 separated from each other.

Thus, the piezoelectric element unit 110 has the ring pattern 111 and the connecting pattern 112, and the upper electrode 130 has the upper ring electrode 131 and the upper connecting electrode 132. In addition, the lower electrode 120 has the lower ring electrode 121 and the lower connecting electrode 122.

For example, the laser LB may be a picosecond laser or a femtosecond laser.

According to the present example embodiments, the piezoelectric element unit may focus the acoustic pressure on the target position. Thus, the acoustic pressure may not be focused in other areas except for the target position, and the cell damage like a burn may be prevented in the ultrasonic treatment. Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A ultrasonic element comprising:
a lower electrode;
a piezoelectric element unit having a plurality of concentric ring patterns over the lower electrode; and
an upper electrode over the piezoelectric element unit.

2. The ultrasonic element of claim 1, wherein
the piezoelectric element unit further comprises a connecting pattern along a radial direction,
the connecting pattern connects the concentric ring patterns, and
the upper electrode comprises:
upper ring electrodes over the concentric ring patterns, the upper ring electrodes being spaced apart from each other; and
an upper connecting electrode over the connecting pattern, wherein the upper connecting electrode connects the upper ring electrodes with each other.

3. The ultrasonic element of claim 1, wherein the piezoelectric element unit comprises a base with the concentric ring patterns being over the base, and the lower electrode is entirely beneath the base.

4. The ultrasonic element of claim 1, wherein
the piezoelectric element unit further comprises a connecting pattern along a radial direction,
the concentric ring patterns are separated from one another,
the connecting pattern connects the concentric ring patterns such that the concentric ring patterns are connected only by way of the connecting pattern, and
the lower electrode comprises:
lower ring electrodes beneath the concentric ring patterns, the lower ring electrodes being spaced apart from each other; and
a lower connecting electrode beneath the connecting pattern, wherein the lower connecting electrode connects the lower ring electrodes with each other.

5. An acoustic pressure focusing device comprising:
an ultrasonic element, comprising:
a lower electrode;
a piezoelectric element unit having a plurality of concentric ring patterns over the lower electrode; and
an upper electrode over the piezoelectric element unit;
an absorbing part at a rear of the ultrasonic element, the absorbing part being configured to absorb an ultrasonic wave generated by the ultrasonic element;
an inner housing enclosing an outer surface of the ultrasonic element and the absorbing part; and
an outer housing within which the inner housing is received, wherein a front of the ultrasonic element is free from being covered by the outer housing such that the front of the ultrasonic element is exposed to an outside environment.

6. The acoustic pressure focusing device of claim 5, further comprising:
a coating layer covering the outer housing and the ultrasonic element.

7. The acoustic pressure focusing device of claim 6, wherein the coating layer is filled in a gap in the ultrasonic element.

8. The acoustic pressure focusing device of claim 7, further comprising:
an impedance matching part between the upper electrode and the coating layer, or in the gap of the ultrasonic element.
